(19) United States
(12) Patent Application Publication
(10) Pub. No.: US 2026/0271718 A1
(43) Pub. Date: Sep. 10, 2026

(54) STRUCTURE WITH ALTERNATE POLARITY THERMOELECTRIC MATERIALS AND METHOD TO FORM SAME

(71) Applicant: GlobalFoundries U.S. Inc., Malta, NY (US)

(72) Inventors: Parnika Gupta, Leuven (BE); Bartlomiej J. Pawlak, Leuven (BE); Christian A. Witt, Hamburg (DE)

(21) Appl. No.: 19/069,314

(22) Filed: Mar. 4, 2025

(51) Int. Cl. H01L 23/38; H01L 23/00; H01L 25/00; H01L 25/065; H10N 10/852

(52) U.S. Cl. CPC H10W 40/28; H10N 10/852; H10W 90/00; H10W 80/312; H10W 80/327; H10W 90/288; H10W 90/792

(57) ABSTRACT

The disclosure provides a structure with alternate polarity thermoelectric materials and methods to form the same. A structure of the disclosure includes a bonding layer between a first die and a second die. The bonding layer includes a set of contact pads coupling a conductive area of the first die to a conductive area of the second die. A first thermoelectric material is connected to the set of contact pads. A second thermoelectric material is also connected to the set of contact pads. The first thermoelectric material and the second thermoelectric material have different conductivity types.

### BACKGROUND

The present disclosure relates to integrated circuit (IC) packages and, more particularly, to an IC package structure with alternate polarity thermoelectric materials.

Dissipating heat to maintain desired amounts of temperature uniformity is a technical challenge in the realm of IC manufacturing. The need to dissipate heat to maintain temperature uniformity may be especially pronounced in the case of multi-die stacks and in products with advanced packaging. As the total number of dies in a product increases with three-dimensional stacking/bonding, the difficulty of thermal management further increases because of these dies may have different operating parameters, and thus different operating temperatures and/or varying amounts of thermal interaction with adjacent dies. In addition, differences in thickness between individual dies in the stack may further contribute to temperature differences within a product as it operates. Many products also offer dynamic power consumption, i.e., differences in electrical operation (and thus differences in thermal parameters) under varying conditions. In certain circumstances, these technical concerns may produce undesirable hotspots on a device.

### SUMMARY

All aspects, examples and features mentioned below can be combined in any technically possible way.

An aspect of the disclosure provides a structure including: a bonding layer between a first die and a second die, wherein the bonding layer includes: a set of contact pads coupling a conductive area of the first die to a conductive area of the second die; a first thermoelectric material connected to the set of contact pads, and a second thermoelectric material connected to the set of contact pads, wherein the first thermoelectric material and the second thermoelectric material have different conductivity types.

Another aspect of the disclosure provides a structure including: a first die having a first integrated circuit (IC) component therein; a second die over the first die and having a second IC component therein; a bonding layer between the first die and the second die, wherein the bonding layer couples the first die to the second die and further includes: a set of contact pads coupling a conductive area of the first die to a conductive area of the second die; a first thermoelectric material connected to the set of contact pads, and a second thermoelectric material connected to the set of contact pads, wherein the first thermoelectric material and the second thermoelectric material have different conductivity types.

Additional aspects of the disclosure provide a method including: forming a bonding layer between a first die and a second die, wherein the bonding layer includes: a set of contact pads coupling a conductive area of the first die to a conductive area of the second die; a first thermoelectric material connected to the set of contact pads, and a second thermoelectric material connected to the set of contact pads, wherein the first thermoelectric material and the second thermoelectric material have different conductivity types.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a structure according to embodiments of the disclosure.

FIG. 2 shows an expanded cross-sectional view of a structure according to embodiments of the disclosure.

FIG. 3 shows a plan view of a structure according to embodiments of the disclosure.

FIGS. 4-10 depict cross-sectional views of a method to form a structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides an IC structure with alternate polarity thermoelectric materials and methods to form the same. A structure of the disclosure includes a bonding layer between a first die and a second die. The bonding layer includes a set of contact pads coupling a conductive area of the first die to a conductive area of the second die. A first thermoelectric material is connected to the set of contact pads. A second thermoelectric material is also connected to the set of contact pads. The first thermoelectric material and the second thermoelectric material have different conductivity types.

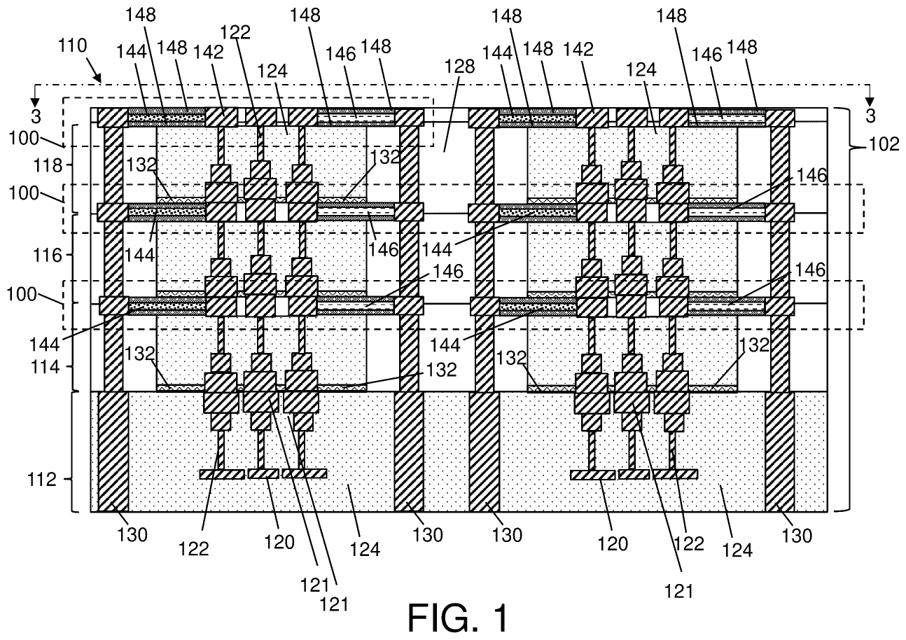

Referring to FIG. 1, a structure 100 according to the disclosure may be included in a stack 110 of integrated circuit dies. Stack 110 may include, e.g., a first integrated circuit die (simply “die” hereafter) 112, a second die 114, a third die 116, and a fourth die 118. Four dies 112, 114, 116, 118 are shown by example, but stack 110 may include fewer than four dies or more than four dies. Each die 112, 114, 116, 118 in stack 110 may include conductive wires, semiconductor materials, and/or insulative materials to electrically separate active components within each die 112, 114, 116, 118 and electrical pathways therebetween. Stack 110 and portions of dies 112, 114, 116, 118 thereof shown in FIG. 1 are only a portion of a larger product; e.g., they may be located near the outer periphery of a device, and other active components and/or wiring layers within each die 112, 114, 116, 118 may be located in horizontally distal locations not specifically shown.

Each die 112, 114, 116, 118 in stack 110 may include sets of metal wires 120 formed of conductive material extending horizontally through portions of each die 112, 114, 116, 118 (including left to right or into or out of the cross-section shown). Each die 112, 114, 116, 118 of stack 110 also may include vias 122 of conductive material extending vertically through portions of each die 112, 114, 116, 118 for electrically coupling metal wires 120 together. Metal wires 120 and vias 122 may include copper (Cu), aluminum (Al), and/or any other currently known or later developed conductive material(s) appropriate for electrical wiring an IC device. First die 112 also may include, e.g., active circuitry 121 such as feedback circuitry, temperature sensors for thermal management, etc. Active circuitry 121 may extend into or out of the plane of the cross-sectional view in FIG. 1, and thus active circuitry 121 may represent only a portion of the above-noted components in first die 112. Metal wires 120 and vias 122 may be formed within dielectric layers 124, 126, and adjacent a gap-filling dielectric 128. Dielectric layer 124 may have metal wires 120 and vias 122 therein, whereas dielectric layer 126 additionally may be for housing at least certain parts of thermally conductive but electrically inactive elements (e.g., structure 100 and thermal rail(s) 130) therein. Gap-filling dielectric 128 may be located between two die stacks (e.g., as shown in FIG. 1) and may include a different dielectric material configured for housing vias for electrical and/or thermal operation of thermoelectric materials discussed herein. According to an example, each dielectric layer 124, 126 and/or gap-filling dielectric 128 may be one or more oxide-based insulators (e.g., etchants with silicon and oxygen elements), one or more nitride-based insulators (e.g., etchants with silicon and nitrogen elements), and/or or other materials having similar properties. In a more specific example, dielectric layer 124 may be an ultra-low K dielectric material (e.g., porous silicon dioxide, porous organosilicate glass, and/or other materials having a dielectric constant of at most approximately 3.9), and dielectric layer 126 may include one or more oxide-based insulators. Dielectric layer(s) 124, 126 and gap-filling dielectric 128 each may be subdivided into individual layers serving different purposes (e.g., isolation layers, inter-level dielectric layers, etch stop layers, etc.), but these subdivisions are omitted from the cross-section of stack 110 for clarity of illustration.

Certain interconnected dies of stack 110 (e.g., first die 112 and second die 114) may include conventional forms of bonding between adjacent dies, e.g., hybrid bonding structures where conductors bond to other conductors (e.g., vias 122 are on vias 122) and dielectric materials bond to other dielectric materials (e.g., dielectric layer(s) 124, 126 are vertically adjacent). To aid the bonding between dies 112, 114 in stack 110, certain areas of the physical interface between dies 112, 114 may include adhesive layers 132 (e.g., polyimide, oxide, silicon carbon nitride, other polymerous materials, and/or similar bonding materials) to provide a mechanically and thermally resilient contact surface for bonding dies 112, 114 together. Adhesive layers 132 are shown on the underside of second die 114 as well as the underside of dies 116, 118 thereover, but adhesive layers 132 may be in other locations in different configurations of stack 110. Polyimide/oxide/silicon carbon nitride etc., may be suitable in adhesive layer(s) 132, e.g., to withstand material stresses and/or high operating temperatures. As discussed herein, certain portions of structure 100 also may include adhesive layer(s) 132 together with additional heat-transmissive materials for directing heat to thermal rail(s) 130.

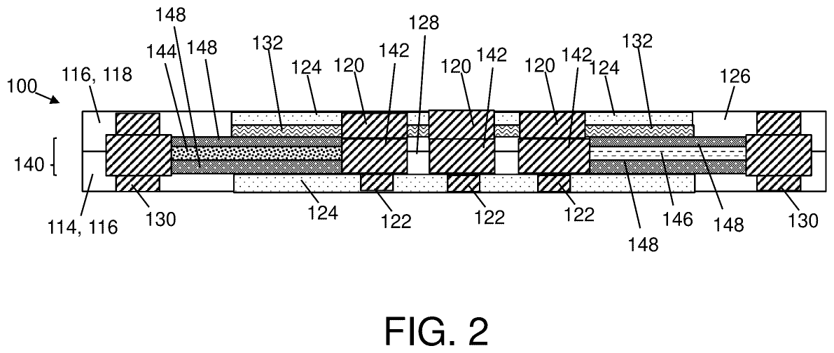

Referring to FIGS. 1 and 2 together, in which FIG. 2 provides an expanded view of the structure 100 within any of the dashed lines of FIG. 1, embodiments of structure 100 are discussed. Structure 100 may include a bonding layer 140 between two dies (e.g., between dies 114, 116, between dies 116, 118, and/or between any two adjacent dies in stack 110). Bonding layer 140 refers to a layer of material located within a lower portion of one die (e.g., die 116 or die 118 as shown) and within an upper portion of an adjacent die (e.g., die 114 or die 116 as shown). Bonding layer 140 may include a set of contact pads 142, each including a conductive material and shaped to electrically connect a conductive area of one die 114, 116 (i.e., metal wire 120 or via 122) to a corresponding conductive area (i.e., another metal wire 120 or via 122) of another die 114, 116. For instance, any metal wire 120 and/or via 122 may be coupled to contact pad(s) 142 such that contact pads 142 define respective electrical pathways between metal wires 120 and/or vias 122. Contact pads 142, in some implementations, may be the only components within bonding layer 140 and/or structure 100 for transmitting of electric currents from one die 114, 116 to another die 116, 118. The other components of bonding layer 140 may instead be configured to dissipate heat away from contact pads 142 as well as any metal wires 120 and/or vias 122 coupled thereto. Metal wires 120 and/or vias 122 in turn may be coupled to other electrically active components (not shown) of a heat management system, e.g., a controller, heat exchanger, etc., in electrical communication with metal wires 120 and/or vias 122. Contact pads 142 may have the same composition or a similar composition to metal wires 120 and vias 122. Contact pads 142 may be distinguishable from other conductors (e.g., metal wires 120 and/or vias 122) solely by being within bonding layer 140.

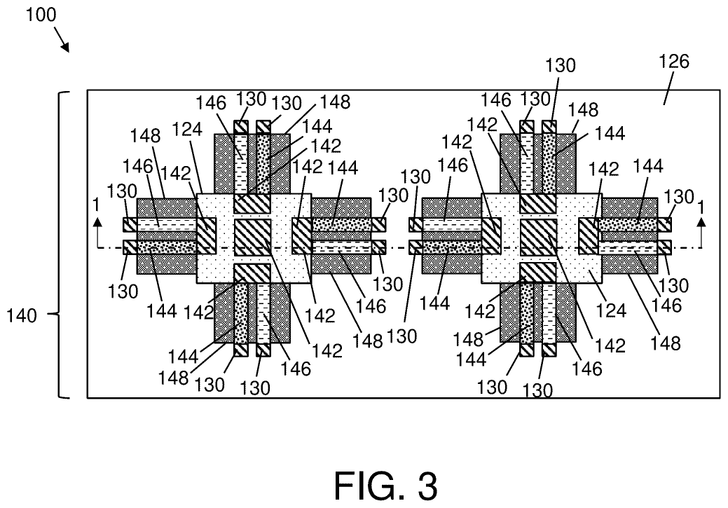

Bonding layer 140 also includes a first thermoelectric material 144 connected to one of contact pads 142 and a second thermoelectric material 146, also connected to one of contact pad 142. As discussed elsewhere herein (e.g., regarding FIG. 3), some contact pads 142 may be connected to first thermoelectric material 144 and second thermoelectric material 146. The term “thermoelectric material” refers to any material exhibiting a significant change in temperature upon application of electric current thereto, or vice versa. Thermoelectric materials 144, 146 in embodiments of the disclosure each may include non-silicon semiconductors having different conductivity types, and optionally, additional dopants to further vary their conductivities. Thermoelectric materials 144, 146 each may include, e.g., First thermoelectric material 144 may have a different conductivity type (e.g., by having a different composition or doping) from second thermoelectric material 146. Thermoelectric materials 144, 146 may be distinguished from each other solely based on their composition and/or doping in some implementations. First thermoelectric material 144 may have p-type conductivity and second thermoelectric material 146 may have n-type conductivity, or vice-versa. P-type material suitable for thermoelectric material(s) 144, 146 may include bismuth antimony telluride (Bi_{0.5}Sb_{1.5}Te₃). N-type material suitable for thermoelectric material(s) 144, 146 may include bismuth telluride selenium (“BTS,” or Bi₂Te_{2.7}Se_{0.3}). Other semiconductor materials and/or dopants (e.g., copper doped with p-type or n-type doping to create thermoelectric behavior) are also possible to provide varying amounts of conductivity in each thermoelectric material 144, 146. The different conductivity types in each thermoelectric material 144, 146 may cause any voltage applied to contact pad 142 to activate either of thermoelectric material(s) 144, 146 to heat or cool the thermal rail(s) 130, depending on whether the polarity is positive or negative. This can provide active thermal control of on-chip hotspots in individual dies within the 3D bonded die stacks.

Thermoelectric materials 144, 146, by being connected to contact pad 142, will dissipate heat away from contact pad 142 when electric current causes heat to accumulate in contact pad 142. Thermoelectric material(s) 144, 146 with opposite doping types optionally may extend in opposite directions, e.g., they each may extend laterally outward from opposing sidewalls of contact pad 142. Such an arrangement may be for structural symmetry and for ease of thermal dissipation during the operation of a device but is not necessarily required in all implementations. Each thermoelectric material 144, 146, however embodied or arranged, may extend horizontally through bonding layer 140 to couple contact pad(s) 142 to thermal rail(s) 130 located at a horizontal end of each bonding layer 140. Thermal rails 130 each may include a thermally conductive material (e.g., one or more metals such as copper (Cu), aluminum (Al), etc., and/or combinations of such materials), but are distinct from other conductive material(s) (e.g., metal wires 120, vias 122, contact pads 142, other conductors discussed herein).

Bonding layer 140 of structure 100 also may include one or more protective layers 148 on an upper surface and/or lower surface of each thermoelectric material 144, 146. Protective layers 148, specifically, may protect each thermoelectric material 144, 146 from electrical and/or thermal interference from any components outside structure 100 or bonding layer 140. In an example implementation, protective layer(s) 148 may include silicon carbonitride (SiCN), SiN or similar electrically insulative materials capable of withstanding the elevated temperatures of thermoelectric materials 144, 146 during operation of structure 100. Protective layer(s) 148, in addition to providing electrical insulation of thermoelectric material(s) 144, 146 from components other than thermal rail(s) 130 and contact pad(s) 142, may confine heat within thermoelectric material(s) 144, 146 such that it propagates only to thermal rail(s) 130. Optionally, protective layers 148 may extend horizontally from one sidewall of contact pad(s) 142 to a corresponding sidewall of thermal rail(s) 130. In further examples (and as illustrated in FIGS. 1, 2), protective layers 148 may extend across and/or physically interface with an entire upper surface and lower surface of a corresponding thermoelectric material(s) 144, 146, such that thermoelectric material(s) 144, 146 are entirely vertically between protective layer(s) 148 along their lengths between contact pad(s) 142 and thermal rail(s) 130. Optionally, protective layer(s) 148 or portions thereof may horizontally forward of, or behind, the plane of the page and thus also may be adjacent thermoelectric material(s) 144, 146.

Referring to FIGS. 1 and 3 together, where FIG. 3 provides a plan view of structure along view line 3 -3 of FIG. 1, example arrangements of thermoelectric material(s) 144, 146 in various embodiments are shown. View line 1 -1 in FIG. 3 also indicates the vantage point for the cross-section of structure 100 shown in FIG. 1. Thermoelectric materials 144, 146 may be provided in a “fan out” arrangement from contact pads 142, such that each contact pad 142 is optionally coupled to multiple thermoelectric materials 144, 146 having different conductivity types. For instance, four contact pads 142 may be located in respective positions along the outer periphery of dielectric layer 124. Each contact pad 142 may include a respective sidewall coupled to thermoelectric materials 144, 146, such that thermoelectric materials 144, 146 with different conductivity types each thermally couple contact pad 142 to thermal rail 130. Thermoelectric materials 144, 146 may be arranged in a cross-shaped configuration as shown in FIG. 3, but other arrangements (e.g., various types of “fan out” shapes in rounded, triangular, and/or other two dimensional polygonal patterns) are possible to dissipate heat away from contact pad(s) 142. Each set of contact pads 142 may be spaced apart by a predetermined separation distance to accommodate any desired number of thermal rails 130 and thermoelectric materials 144, 146 for coupling contact pad(s) 142 to thermal rail(s) 130. As also indicated in FIG. 3, each thermoelectric material 144, 146 may be within and alongside protective layer(s) 148 such that heat transmitted within thermoelectric material 144, 146 is directed to thermal rail(s) 130 and not to other surrounding materials (e.g., dielectric layers 124, 126 and/or gap-filling dielectric 128).

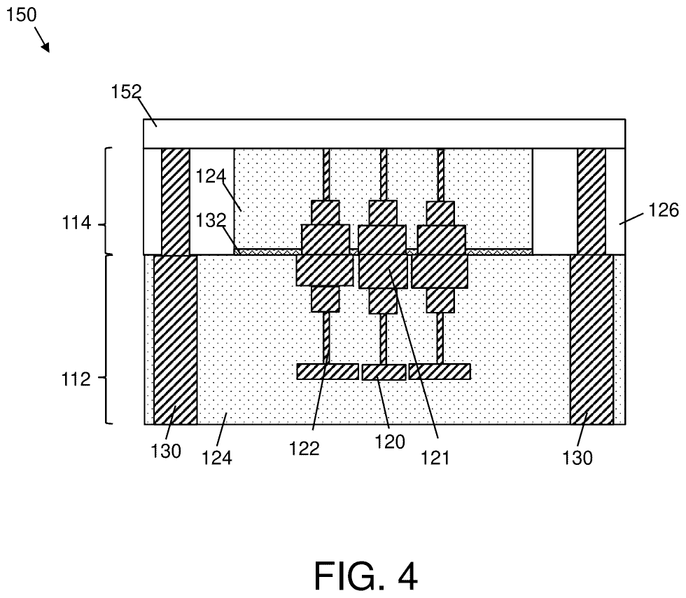

Turning to FIG. 4, the disclosure provides methods of forming structure 100 (FIGS. 1-3). An initial structure 150 may have various conventional heat dissipation features but bonding layer 140 (FIGS. 1-3) is not yet formed. Initial structure 150 includes, e.g., dielectric layer 124 with metal wires 120 and vias 122 therein, and thermal rails 130 located horizontally distal to metal wires 120 and vias 122. Initial structure 150, as an example, is shown to include first die 112 and second die 114, but the processes described herein are equally applicable to any two adjacent dies included in stack 110 (FIG. 1). As also discussed herein, adhesive layer(s) 132 may be along an interface between dies 112, 114 to aid in insulator-to-insulator bonding whereas metallic structures (e.g., metal wires 120, vias 122, thermal rails 130) may be coupled together with metal-to-metal bonding. Dies 112, 114 also may already include dielectric layer(s) 124, 126 and/or gap-filling dielectric 128 therein. An uppermost die (e.g., second die 114) may have a dielectric layer 152 thereon, e.g., any dielectric material discussed elsewhere herein or comparable insulative material. Dielectric layer 152 may have the same composition or a similar composition to dielectric layer(s) 124, 126 and/or gap-filling dielectric 128. In addition, thermal rails 130 may be covered by (and thus below) dielectric layer 152. Dielectric layer 152 may differ from dielectric layers 124, 126 and/or gap-filling dielectric 128 by operating as a foundational material to create an embodiment of bonding layer 140 (FIGS. 1-3) for structure 100 (FIGS. 1-3).

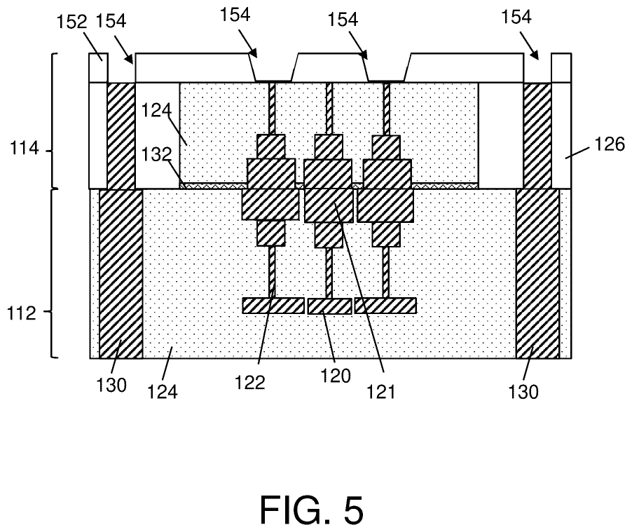

FIG. 5 depicts continued processing, e.g., by forming a set of openings 154 within dielectric layer 152 over metal wires 120 and/or vias 122. Openings 154, however shaped or positioned, may be formed within dielectric layer 152 to enable coupling of subsequently formed contact pads to metal wires 120 and/or vias 122 in the uppermost die (e.g., second die 114 as shown). Openings 154 may be formed by depositing a temporary masking layer (not shown) on dielectric layer 152 with gaps shaped to create openings 154, and removing dielectric layer 152 within the gaps. Openings 154 also may be positioned over portions of thermal rails 130 to enable forming of additional thermal rail 130 material within dielectric layer 152.

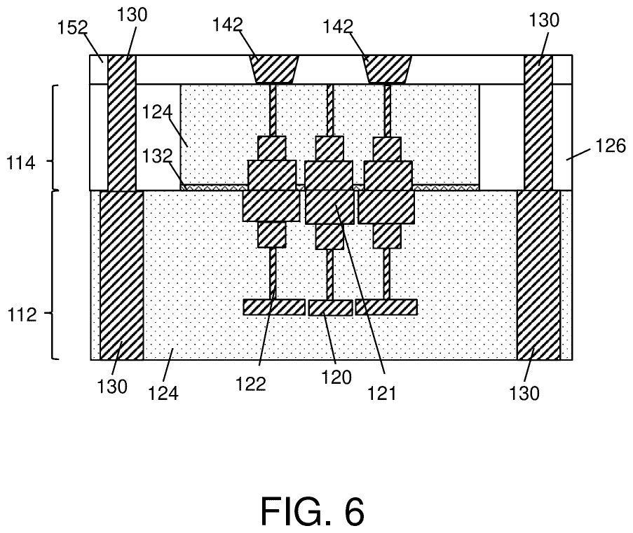

FIG. 6 illustrates forming additional conductive material within openings 154 (FIG. 5) to create contact pads 142 and additional portions of thermal rail 130. Any conductive material formed in contact with thermal rail(s) 130 and in locations horizontally external to metal wires 120 and vias 122 may extend the length of thermal rail(s) 130. Any conductive material formed on metal wire(s) 120 and/or via(s) 122 may create contact pads 142. Contact pads 142 need not have similar dimensions to metal wire(s) 120 and/or via(s) 122, and contact pads 142 optionally may be larger in size to aid in electrically coupling metal wire(s) 120 and/or via(s) 122 together, or otherwise enabling greater heat transmission to thermoelectric material(s) 144, 146 (FIGS. 1-3) formed later in processing. Thermal rail(s) 130 and contact pad(s) 142 may be similar or identical in composition, and thus may be formed together in a single instance of depositing conductive material and/or set of depositions. Thermal rail(s) 130 and contact pad(s) 142 thus may be distinguishable from each other based on whether they are located over other portions of thermal rail(s) 130, or over metal wire(s) 120 and/or via(s) 122.

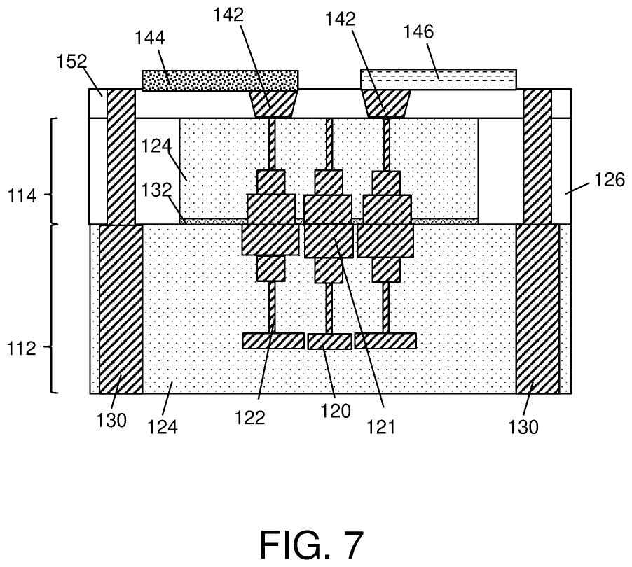

FIG. 7 depicts an example process to form thermoelectric material(s) 144, 146 on contact pad(s) 142. The forming of thermoelectric material(s) 144, 146 may include, e.g., forming a layer of semiconductor material(s) by deposition and/or epitaxial growth, then masking and removing selected portions of the semiconductor material such that heat remains over contact pad(s) 142 and extends over dielectric layer 152 over a desired horizontal length. As discussed herein, thermoelectric material(s) 144, 146 may have different conductivity types due to their compositions and/or doping. Thermoelectric materials 144, 146, as examples, may include bismuth antimony telluride and bismuth telluride selenium, respectively. Optionally, after the semiconductor material is formed and shaped, the processed material may not yet be in contact with thermal rail(s) 130. The material(s) then may be doped (e.g., by implantation or other currently known or later developed doping processes) to define thermoelectric materials 144, 146 with different conductivity types. These thin film thermoelectric materials can also be deposited through electrodeposition and patterned to form lateral thermoelectric legs (p-type and n-type) connected in series.

Each thermoelectric material 144, 146, where applicable, may be doped separately by forming a temporary mask over one of the two thermoelectric materials 144, 146, doping the thermoelectric material 144, 146 not covered by the temporary mask, and then removing the temporary mask. In such cases, each thermoelectric material 144, 146 may include copper and/or other non-semiconductor materials with p-type or n-type dopants to provide thermoelectric properties. In any case, thermoelectric materials 144 ,146 each may be doped to have different conductivity types from each other, such that different voltage polarities will cause heat transmission through thermoelectric material(s) 144, 146 with the corresponding conductivity type.

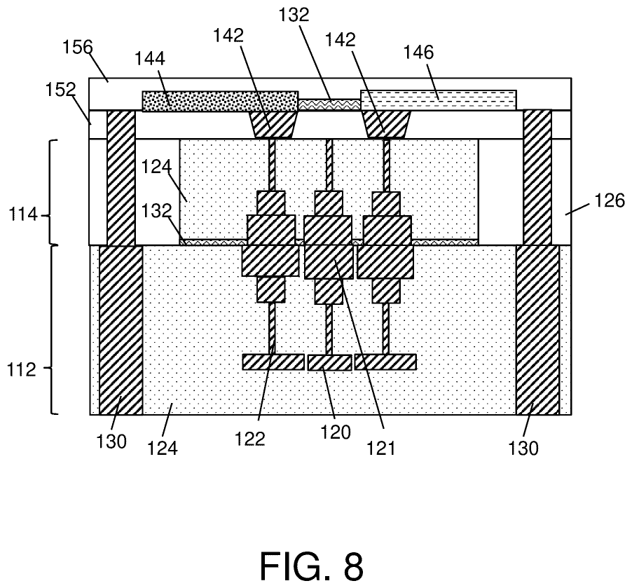

Turning to FIG. 8, the disclosure may include forming a dielectric layer 156 to cover thermoelectric materials 144, 146 as well as any portions of dielectric layer 152 and thermal rails 130 not covered by thermoelectric materials 144, 146. Capping layers above 144,146 are provided to prevent diffusion of thermoelectric materials into the surrounding dielectric. Dielectric layer 156 may have a similar or identical composition to dielectric layer 152 and is identified separately from dielectric layer 152 solely because it may be formed in a different phase of processing. Dielectric layer 156 optionally may also include one or more adhesive layer(s) 132 such polyimide and/or other electrically insulative adhesive substances) to assist in bonding dielectric layers 152, 156 together. Although not specifically shown in FIG. 8 et seq., dielectric layer 152 optionally may include adhesive layer 132 instead of, or in addition to, dielectric layer 156. In any case, adhesive layer 132 and/or dielectric layer 156 may be formed by deposition and/or planarization according to any currently known or later developed technique to form such material(s).

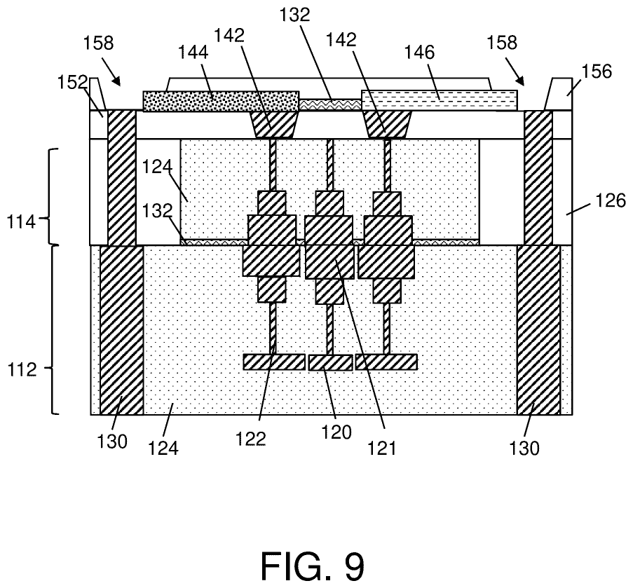

FIG. 9 depicts forming openings 158 within dielectric layer 156 to expose thermal rails 130 and portions (e.g., horizontally outer ends) of thermoelectric materials 144, 146. Openings 158 may be formed by etching with the aid of a temporary mask (not shown) via the same or similar techniques implemented to form openings 154, e.g., as discussed relative to FIG. 5. Openings 158, moreover, may be formed by one or more selective etchants such that thermal rails 130 and thermoelectric materials 144, 146 are substantially unaffected when forming openings 158.

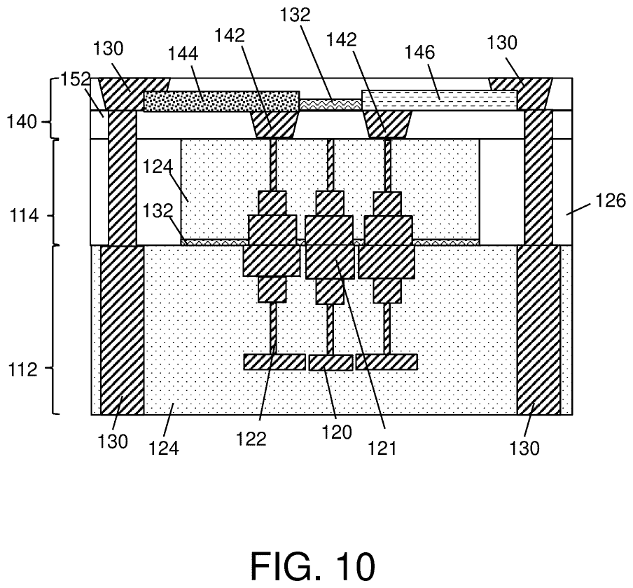

Referring now to FIG. 10, methods of the disclosure may include forming an additional portion of thermal rail 130 to connect each thermal rail 130 to one of thermoelectric materials 144, 146. Forming additional portions of thermal rail 130 may include depositing and planarizing of conductive material(s) through the same or similar techniques to form other portions of thermal rail 130 discussed herein. Although the additional portions of thermal rail 130 formed to connect to thermoelectric materials 144, 146 may have different dimensions (e.g., they may be horizontally wider than other portions of thermal rail 130), they may conduct heat to or from underlying portions of thermal rail 130 and thus are considered part of the same structure. The lateral contact portion of the thermal rail 130, where it is fanning out of the chip area and onto the dielectric gap-filled area, can include thermally conductive and/or electrically insulating contact materials. Such materials can be in contact with the vertical 130 thermal rails for heat dissipation but conditionally form electrically conductive contacts with the vertical 130 thermal rails when electrical input (voltage or current) is provided for thermoelectric operation.

Embodiments of the disclosure provide various technical and commercial advantages, examples of which are discussed herein. For example, thermoelectric material(s) 144, 146 may improve cooling over a limited surface area by using electrically active materials to convert electricity into heat for dissipation to thermal rails 130. Thermoelectric material(s) 144, 146 may be in areas of a product that do not otherwise include active components (i.e., they may be within bonding layer 140) and thus provide additional thermal management mechanisms. In addition, embodiments of structure 100 provide ‘waste power recovery’ by converting excessive voltage magnitudes into thermal energy that can then be provided to thermal rails 130, thereby lowering the temperature of metal wires 120 and/or vias 122. The electrically-driven operation of thermoelectric material(s) 144, 146 also allows hot spots to be more easily detected and managed, e.g., by identifying whether currents are being triggered only in certain thermoelectric material(s) 144, 146. The disclosure also enables thermal rail(s) 130 and any heat management structures connected thereto (e.g., heat sinks or similar assemblies) to be located horizontally outside the perimeter of any active device components.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a bonding layer between a first die and a second die, wherein the bonding layer includes:
a set of contact pads coupling a conductive area of the first die to a conductive area of the second die;
a first thermoelectric material connected to the set of contact pads, and
a second thermoelectric material connected to the set of contact pads, wherein the first thermoelectric material and the second thermoelectric material have different conductivity types.

2. The structure of claim 1, wherein the first thermoelectric material and the second thermoelectric material each include a semiconductor.

3. The structure of claim 2, wherein the first thermoelectric material includes bismuth antimony telluride.

4. The structure of claim 2, wherein the second thermoelectric material includes bismuth telluride selenium.

5. The structure of claim 1, wherein the first thermoelectric material and the second thermoelectric material extend laterally outward from opposing sidewalls of the set of contact pads.

6. The structure of claim 1, further comprising a silicon carbonitride (SiCN) layer on an upper surface or a lower surface of the bonding layer.

7. The structure of claim 1, wherein the first thermoelectric material and the second thermoelectric material each couple the set of contact pads to a respective thermal rail within the bonding layer.

8. A structure comprising:
a first die having a first integrated circuit (IC) component therein;
a second die over the first die and having a second IC component therein; and
a bonding layer between the first die and the second die, wherein the bonding layer couples the first die to the second die and further includes:
a set of contact pads coupling a conductive area of the first die to a conductive area of the second die;
a first thermoelectric material connected to the set of contact pads, and
a second thermoelectric material connected to the set of contact pads, wherein the first thermoelectric material and the second thermoelectric material have different conductivity types.

9. The structure of claim 8, wherein the first thermoelectric material and the second thermoelectric material each include a semiconductor.

10. The structure of claim 9, wherein the first thermoelectric material includes bismuth antimony telluride.

11. The structure of claim 9, wherein the second thermoelectric material includes bismuth telluride selenium.

12. The structure of claim 8, wherein the first thermoelectric material and the second thermoelectric material extend laterally outward from opposing sidewalls of the set of contact pads.

13. The structure of claim 8, further comprising a silicon carbonitride (SiCN) layer on an upper surface or a lower surface of bonding layer.

14. The structure of claim 8, wherein the first thermoelectric material and the second thermoelectric material each couple the set of contact pads to a respective thermal rail within the bonding layer.

15. A method comprising:
forming a bonding layer between a first die and a second die, wherein the bonding layer includes:
a set of contact pads coupling a conductive area of the first die to a conductive area of the second die;
a first thermoelectric material connected to the set of contact pads, and
a second thermoelectric material connected to the set of contact pads, wherein the first thermoelectric material and the second thermoelectric material have different conductivity types.

16. The method of claim 15, wherein the first thermoelectric material and the second thermoelectric material each include a semiconductor.

17. The method of claim 16, wherein the first thermoelectric material includes bismuth antimony telluride.

18. The method of claim 16, wherein the second thermoelectric material includes bismuth telluride selenium.

19. The method of claim 15, further comprising coupling a silicon carbonitride (SiCN) layer to an upper surface or a lower surface of the bonding layer.

20. The method of claim 15, further comprising coupling the bonding layer to a thermal rail within the first die or the second die.
